(19) United States
(12) Patent Application Publication
(10) Pub. No.: US 2014/0192628 A1
(43) Pub. Date: Jul. 10, 2014

(54) PIEZOELECTRIC VIBRATING PIECE, PIEZOELECTRIC VIBRATOR, OSCILLATOR, ELECTRONIC APPARATUS, AND RADIO-CONTROLLED TIMEPIECE

(71) Applicant: SII Crystal Technology Inc., Chiba-shi (JP)

(72) Inventor: Masanori TAMURA, Chiba-shi (JP)

(73) Assignee: SII Crystal Technology Inc., Chiba-shi (JP)

(21) Appl. No.: 14/148,326

(22) Filed: Jan. 6, 2014

(30) Foreign Application Priority Data
Jan. 10, 2013 (JP) 2013-002910

(51) Int. Cl. H03H 9/21; H03B 5/32; G04C 9/00; H01L 41/053

(52) U.S. Cl. CPC H03H 9/21; H01L 41/053; H03B 5/32; G04C 9/02
USPC 368/159; 310/370; 310/344; 331/158

(57) ABSTRACT

A piezoelectric vibrating piece includes a pair of vibrating arm portions, a base portion which is arranged between a pair of vibrating arm portions, and connecting portions which connect proximal end portions of a pair of vibrating arm portions and a proximal end portion of the base portion. Narrow width portions are provided at the base of the base portion.

### RELATED APPLICATIONS

This application claims priority under 35 U.S.C. §119 to Japanese Patent Application No. 2013-002910 filed on Jan. 10, 2013, the entire content of which is hereby incorporated by reference.

### BACKGROUND OF THE INVENTION

1. Field of the Invention

The present invention relates to a piezoelectric vibrating piece, a piezoelectric vibrator, an oscillator, an electronic apparatus, and a radio-controlled timepiece.

2. Background Art

In the related art, a piezoelectric vibrating piece in which a base portion is provided between a pair of vibrating arm portions, and proximal end portions of the vibrating arm portions and a proximal end portion of the base portion are connected by connecting portions is known. In the piezoelectric vibrator, the base portion of the piezoelectric vibrating piece is mounted on a base substrate of a package, such that the piezoelectric vibrating piece is accommodated inside the package (see JP-A-2006-345517 and JP-A-2006-345519).

When the profile of the piezoelectric vibrating piece is formed by wet etching, it is known that an odd-shaped portion, called “etching residue”, is formed due to crystal anisotropy of a piezoelectric material. In a case of the above-described piezoelectric vibrating piece, in particular, “etching residue” is likely to occur near the base of the vibrating arm portion and the base of the base portion.

If “etching residue” is formed and remains as an odd-shaped portion, during vibration of the piezoelectric vibrating piece, when external impact is applied, or the like, cracks or defects of the piezoelectric vibrating piece may occur near the base of the vibrating arm portion or the base portion by stress concentration. That is, “etching residue” affects the mechanical characteristic of the piezoelectric vibrating piece. As a result of “etching residue” affecting the vibration characteristic of the vibrating arm portion, a desired output frequency may not be stably obtained. That is, “etching residue” affects the vibration characteristic of the piezoelectric vibrating piece.

While it is possible to reduce the amount of “etching residue” by expanding the interval between the base portion and the vibrating arm portions, in this case, there is a problem in that it is not possible to attain reduction in size of the piezoelectric vibrating piece.

That is, as described above, in the piezoelectric vibrating piece which has a pair of vibrating arm portions and the base portion provided between a pair of vibrating arm portions, a technique for attaining reduction in size and reducing the influence on the mechanical characteristic of the odd-shaped portion near the base of the base portion or the vibration characteristic has not been yet disclosed.

### SUMMARY OF THE INVENTION

The invention has been accomplished in consideration of the above-described situation, and an object of the invention is to provide a piezoelectric vibrating piece, a piezoelectric vibrator, an oscillator, an electronic apparatus, and a radio-controlled timepiece capable of attaining reduction in size and reducing the influence on the mechanical characteristic of the odd-shaped portion caused by etching residue or the vibration characteristic.

In order to solve the above-described problem and to attain the related object, according to a first aspect of the invention, there is provided a piezoelectric vibrating piece including a pair of vibrating arm portions, a base portion which is arranged between a pair of vibrating arm portions, and connecting portions which connect proximal end portions of a pair of vibrating arm portions and a proximal end portion of the base portion. Narrow width portions are provided at the base of the base portion.

With this configuration, the narrow width portions are provided at the base of the base portion, whereby etching residue is formed in a recessed space by the narrow width portions. Accordingly, since etching residue does not remain as “odd-shaped portion”, it becomes possible to reduce the influence on the mechanical characteristic of the odd-shaped portion or the vibration characteristic. Since it is not necessary to expand the interval between the base portion and the vibrating arm portions, it is possible to attain reduction in size of the piezoelectric vibrating piece. The narrow width portions are provided, whereby the vibration of the vibrating arm portions is attenuated with the narrow width portions, and it is possible to prevent “vibration leakage” when vibration propagates from the vibrating arm portion toward the package side through the base portion.

According to a second aspect of the invention, in the piezoelectric vibrating piece, at the base of the base portion, the narrow width portions are formed such that the side surface of the base portion has a curved shape which is recessed inwardly.

With this configuration, the side surface of the base portion has a curved shape which is recessed inwardly, it is possible to reduce the amount of etching residue itself formed in the narrow width portions. For example, when the side surface has a planar shape, etching residue is remarkably formed at the corner at which the planes intersect each other. Meanwhile, when the side surface has a curved shape, the amount of etching residue decreases compared to the planar shape. Accordingly, it becomes possible to reduce the influence on the mechanical characteristic of the odd-shaped portion or the vibration characteristic.

According to a third aspect of the invention, in the piezoelectric vibrating piece, the side surface of each of the connecting portions has a curved shape and is connected to the curved shape of the side surface of the base portion, and the curved shapes substantially the same radius of curvature.

With this configuration, the side surface of each of the connecting portions and the side surface of the base portion are connected together with curved shapes substantially having the same radius of curvature, that is, the side surface of each of the connecting portions and the side surface of the base portion are “smoothly” connected together. Accordingly, since it is possible to more effectively reduce the amount of etching residue, it becomes possible to reduce the influence on the mechanical characteristic of the odd-shaped portion or the vibration characteristic.

According to a fourth aspect of the invention, there is provided a piezoelectric vibrator including the above-described piezoelectric vibrating piece, and a package in which a cavity is formed. The base portion is mounted on a base substrate of the package inside the cavity.

According to a fifth aspect of the invention, there is provided an oscillator including the above-described piezoelectric vibrator. The piezoelectric vibrator is electrically connected to an integrated circuit as an oscillator.

According to a sixth aspect of the invention, there is provided an electronic apparatus including the above-described piezoelectric vibrator. The piezoelectric vibrator is electrically connected to a counter unit.

According to a seventh aspect of the invention, there is provided a radio-controlled timepiece including the above-described piezoelectric vibrator. The piezoelectric vibrator is electrically connected to a filter unit.

According to the piezoelectric vibrating piece of the invention, the narrow width portions are provided at the base of the base portion, thereby reducing the influence of etching residue on the mechanical characteristic of the piezoelectric vibrating piece or the vibration characteristic.

Since it is not necessary to expand the interval between the base portion and the vibrating arm portions, it is possible to attain reduction in size of the piezoelectric vibrating piece.

That is, according to the invention, it becomes possible to provide a piezoelectric vibrating piece capable of attaining reduction in size and reducing the influence on the mechanical characteristic of the odd-shaped portion formed by etching residue or the vibration characteristic.

According to the piezoelectric vibrator, the oscillator, the electronic apparatus, and the radio-controlled timepiece of the invention, it is possible to improve operation reliability.

### BRIEF DESCRIPTION OF THE DRAWINGS

FIG. 1 is an appearance perspective view of a piezoelectric vibrator according to an embodiment of the invention.

FIG. 2 is an internal configuration diagram of the piezoelectric vibrator shown in FIG. 1.

FIG. 3 is a sectional view of the piezoelectric vibrator taken along the line A-A of FIG. 2.

FIG. 4 is an exploded perspective view schematically showing the piezoelectric vibrator shown in FIG. 1.

FIG. 5 is a diagram showing a state where a base portion is omitted in a sectional view taken along the line B-B of FIG. 4.

FIG. 6 is a configuration diagram showing an embodiment of an oscillator according to the invention.

FIG. 7 is a configuration diagram showing an embodiment of an electronic apparatus according to the invention.

FIG. 8 is a configuration diagram showing an embodiment of a radio-controlled timepiece according to the invention.

### DETAILED DESCRIPTION OF THE PREFERRED EMBODIMENTS

Hereinafter, a piezoelectric vibrating piece, a piezoelectric vibrator, an oscillator, an electronic apparatus, and a radio-controlled timepiece according to an embodiment of the invention will be described.

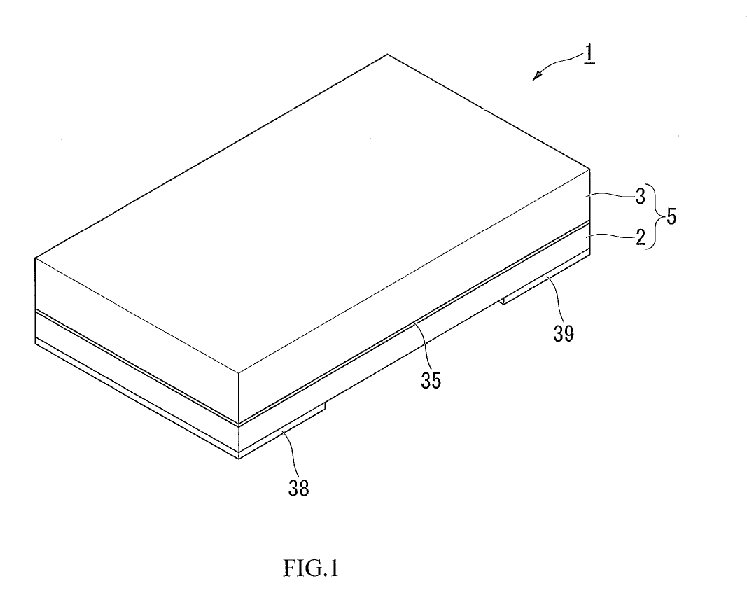

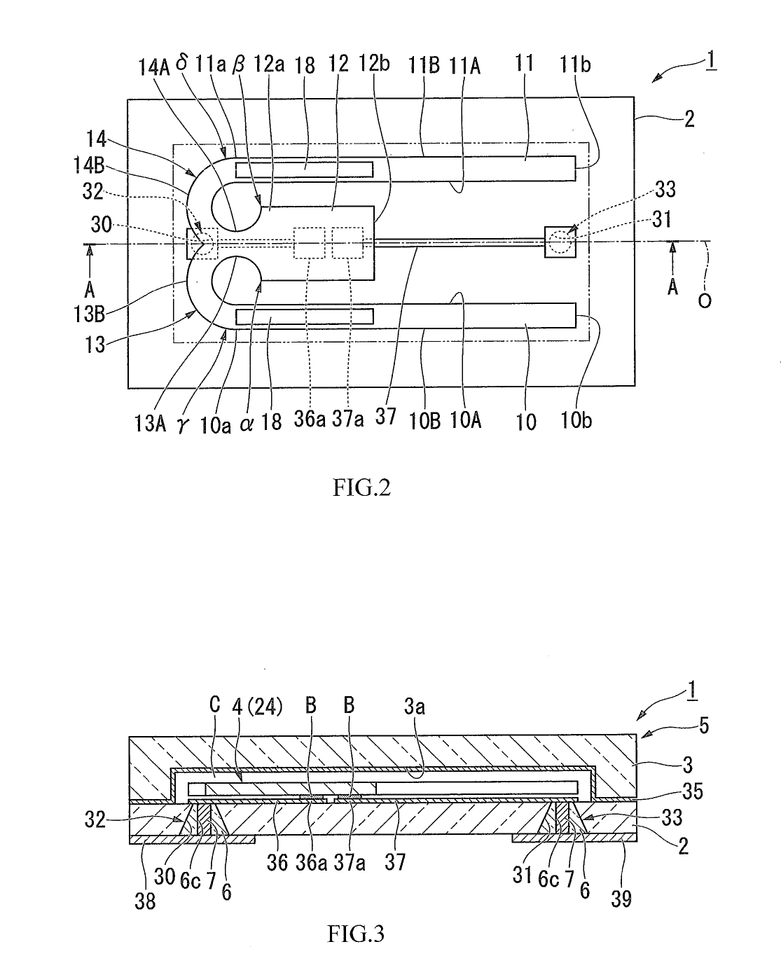

As shown in FIGS. 1 to 5, a piezoelectric vibrator 1 of this embodiment is a surface mounting type piezoelectric vibrator 1 which includes a boxlike package 5 having a base substrate 2 and a lead substrate 3 anode-bonded through a bonding material 35, and a piezoelectric vibrating piece 4 accommodated in a cavity C sealed inside the package 5.

The piezoelectric vibrating piece 4 and external electrodes 38 and 39 provided on the base substrate 2 are electrically connected by a pair of through electrodes 32 and 33 passing through the base substrate 2.

The piezoelectric vibrating piece 4 includes a tuning fork type piezoelectric plate 24 formed of a piezoelectric material, such as crystal, lithium tantalate or lithium niobate, and vibrates by the application of a predetermined voltage.

The piezoelectric plate 24 includes a pair of vibrating arm portions 10 and 11 which are arranged in parallel with the center axis O interposed therebetween, a base portion 12 which is arranged between a pair of vibrating arm portions 10 and 11 and fixed to the outside, and a pair of connecting portions 13 and 14 which connect proximal end portions 10a and 11a of a pair of vibrating arm portions 10 and 11 and a proximal end portion 12a of the base portion 12.

The base portion 12 extends toward a distal end portion 12b, and “narrow width portions 13A and 14A” with the width of the base portion 12 narrowed compared to the distal end portion 12b are formed at the base of the base portion 12. A pair of connecting portions 13 and 14 are formed in a shape bent from the proximal end portions 10a and 11a of a pair of vibrating arm portions 10 and 11 toward the proximal end portion of the base portion 12. Although the bent connecting portions 13 and 14 have been described, the shape of the connecting portions 13 and 14 is not limited thereto, and may be substantially an L shape or a linear shape.

The side surface of the base portion 12 is formed in a curved shape which is recessed inwardly in each of the “narrow width portions 13A and 14A”. The side surface of each of a pair of connecting portions 13 and 14 has a curved shape, and the narrow width portions 13A and 14A″ of the base portion 12 continue with the portions having a curved shape of the connecting portions 13 and 14. Both curved shapes substantially have the same radius of curvature, that is, both curved shapes are “smoothly” connected together. While the outer side surface (the side surface opposite to the base portion and the vibrating arm portion) of each of the connecting portions 13 and 14 has a curved shape, the outer side surface of each of the connecting portions 13 and 14 is not limited thereto, and may have a planar shape.

A pair of vibrating arm portions 10 and 11 are configured such that excitation electrodes having a first excitation electrode 15 and a second excitation electrode 16 which vibrate a pair of vibrating arm portions 10 and 11 are provided on the surface of a piezoelectric body (piezoelectric plate 24) made of a piezoelectric material.

The base portion 12 is configured such that a pair of mounting electrodes (not shown) which electrically connect the first excitation electrode 15 and the second excitation electrode 16 to lead-out electrodes 36 and 37 are provided on the surface of the piezoelectric body (piezoelectric plate 24) made of a piezoelectric material.

The piezoelectric plate 24 includes groove portions 18 which are formed on both principal surfaces of a pair of vibrating arm portions 10 and 11 in the longitudinal direction (extension direction) of the vibrating arm portions 10 and 11. For example, each of the groove portions 18 is substantially formed from the proximal end of corresponding one of the vibrating arm portions 10 and 11 to near the center.

The excitation electrodes having the first excitation electrode 15 and the second excitation electrode 16 are patterned on the outer surfaces of a pair of vibrating arm portions 10 and 11 in a state of being electrically insulated from each other, and cause a pair of vibrating arm portions 10 and 11 to vibrate at a predetermined frequency in a direction close to each other or away from each other. Specifically, for example, the first excitation electrode 15 is primarily provided on the groove portion 18 of the first vibrating arm portion 10 and both side surfaces of the second vibrating arm portion 11. The second excitation electrode 16 is primarily provided on both side surfaces of the first vibrating arm portion 10 and the groove portion 18 of the second vibrating arm portion 11.

The first excitation electrode 15 and the second excitation electrode 16 are electrically connected to the mounting electrodes (not shown) through the lead-out electrodes (not shown) on both principal surfaces of the base portion 12. Accordingly, a voltage is applied to the piezoelectric vibrating piece 4 through the mounting electrodes (not shown).

A pair of vibrating arm portions 10 and 11 include weight metal films (not shown) coated on the outer surfaces for frequency adjustment to adjust the vibration state such that the vibrating arm portions 10 and 11 vibrate within a range of a predetermined frequency. The weight metal films (not shown) include, for example, a coarse adjustment film (not shown) for coarsely adjusting the frequency and a fine adjustment film (not shown) for finely adjusting the frequency.

The frequency adjustment is performed by the weight adjustment of the coarse adjustment film and the fine adjustment film, and the frequency of each of a pair of vibrating arm portions 10 and 11 is adjusted so as to fall within a range of a predetermined target frequency.

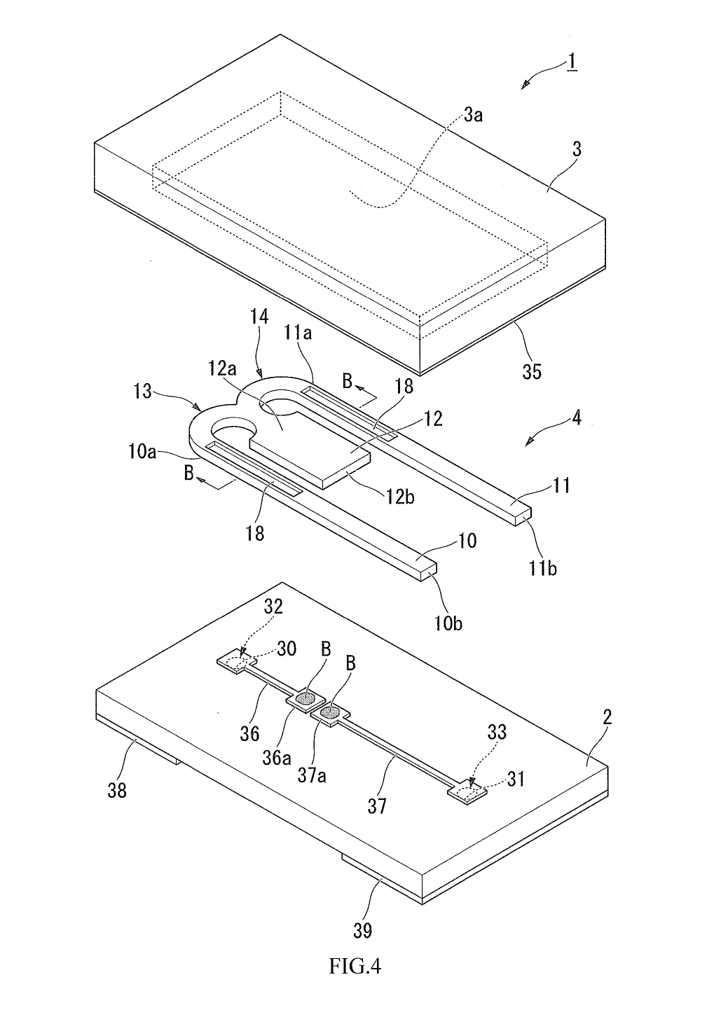

For example, as shown in FIGS. 3 and 4, the piezoelectric vibrating piece 4 is bump-bonded onto the lead-out electrodes 36 and 37 provided on the surface (the surface facing the lead substrate 3) of the base substrate 2 by a bump B, such as gold. In this embodiment, although a glass package has been described, the piezoelectric vibrating piece 4 may be accommodated in a ceramic package having a ceramic base substrate and a metal lead substrate. In this case, the piezoelectric vibrating piece 4 may be bonded by a conductive adhesive.

The first excitation electrode 15 of the piezoelectric vibrating piece 4 is bump-bonded onto the second lead-out electrode 37 through the first mounting electrode (not shown) and the bump B, and the second excitation electrode 16 is bump-bonded onto the first lead-out electrode 36 through the second mounting electrode (not shown) and the bump B.

Accordingly, the piezoelectric vibrating piece 4 is supported in a state of being floated from the surface (the surface facing the lead substrate 3) of the base substrate 2, and the mounting electrodes (not shown) and the lead-out electrodes 36 and 37 are electrically connected together.

The lead substrate 3 is formed in a plate shape using a transparent insulating substrate made of a glass material, such as soda-lime glass. On the bonding surface which is bonded to the base substrate 2, a rectangular concave portion 3a in which the piezoelectric vibrating piece 4 can be accommodated is provided.

The concave portion 3a forms a cavity C, in which the piezoelectric vibrating piece 4 is accommodated, along with the surface (the surface facing the lead substrate 3) of the base substrate 2, when both substrates 2 and 3 are superimposed.

The lead substrate 3 includes a bonding material 35 which is provided on the entire surface facing the base substrate 2. For example, the bonding material 35 is provided on the bonding surface to the base substrate 2 and the entire inner surface of the concave portion 3a. The lead substrate 3 is anode-bonded to the base substrate 2 through the bonding material 35 in a state where the concave portion 3a faces the base substrate 2, and seals the cavity C airtight. In a case of the ceramic package, the ceramic base substrate and the metal lead substrate are bonded together using a bonding material, such as a solder material.

Similarly to the lead substrate 3, the base substrate 2 is formed in a plate shape to be superimposed on the lead substrate 3 using a transparent insulating substrate made of a glass material, such as soda-lime glass. The base substrate 2 includes a pair of through holes 30 and 31 which pass therethrough in the thickness direction and are formed inside the cavity C.

Specifically, for example, of the through holes 30 and 31 of this embodiment, the first through hole 30 is formed at a position facing the proximal end portion 12a of the base portion 12 of the mounted piezoelectric vibrating piece 4. The second through hole 31 is formed at a position facing between the distal end portions 10b and 11b of the vibrating arm portions 10 and 11. The through holes 30 and 31 are formed to have a tapered cross section in which the diameter is gradually reduced from a first surface toward a second surface (a surface facing the lead substrate 3) of the base substrate 2.

In this embodiment, although the through holes 30 and 31 are formed to have a tapered cross section, the invention is not limited thereto. For example, a through hole which passes through the base substrate 2 in the thickness direction at the same diameter may be provided, and in summary, it should suffice that a through hole passes through the base substrate 2.

A pair of through holes 30 and 31 include a pair of through electrodes 32 and 33 which are formed so as to fill the through holes 30 and 31. The through electrodes 32 and 33 are formed by a cylinder 6 and a core portion 7 integrally fixed to the through holes 30 and 31 by sintering, close the through holes 30 and 31 so as to maintain airtightness inside the cavity C, and provide electrical conduction between external electrodes 38 and 39 and the lead-out electrodes 36 and 37.

Specifically, for example, the first through electrode 32 is arranged facing the lead-out electrode 36 between the external electrode 38 and the base portion 12, and the second through electrode 33 is arranged facing the lead-out electrode 37 between the external electrode 39 and the distal end portions 10b and 11b of the vibrating arm portions 10 and 11.

The cylinder 6 is formed by sintering paste-like glass frit.

Specifically, for example, the cylinder 6 is formed in a cylindrical shape having both flat ends and the substantially same thickness as the base substrate 2. The cylinder 6 fixes the core portion 7 which is inserted into a center hole passing through the cylinder 6 in the thickness direction.

In this embodiment, the profile of the cylinder 6 is formed to have a conical shape (tapered cross section) in conformity with the shape of corresponding one of the through holes 30 and 31. The cylinder 6 is sintered in a state of being filled inside corresponding one of the through holes 30 and 31, and firmly fixed to corresponding one of the through holes 30 and 31.

The core portion 7 is a conductive core which is formed in a columnar shape using a metal material, and similarly to the cylinder 6, has both flat ends and the substantially same thickness as the base substrate 2.

The core portion 7 is located at a center hole 6c of the cylinder 6 and firmly fixed to the cylinder 6 by sintering the cylinder 6. Each of the through electrodes 32 and 33 has electrical conductivity by the conductive core portion 7.

The base substrate 2 is configured such that a pair of lead-out electrodes 36 and 37 patterned by a conductive material (for example, aluminum) are provided on the surface on the bonding surface side to which the lead substrate 3 is bonded. A pair of lead-out electrodes 36 and 37 are electrically connected to the first through electrode 32 of a pair of through electrodes 32 and 33 and the second mounting electrode (not shown) of the piezoelectric vibrating piece 4, and is electrically connected to the second through electrode 33 and the first mounting electrode (not shown) of the piezoelectric vibrating piece 4.

Specifically, for example, the first lead-out electrode 36 is provided so as to extend from the first through electrode 32 arranged in a pair of connecting portions 13 and 14 toward a support portion 36a arranged in the distal end portion 12b of the base portion 12 in the axial direction of the center axis O.

The first lead-out electrode 36 supports the distal end portion 12b of the base portion 12 by bump-bonding using the bump B of the support portion 36a in a state of being floated from the surface (the surface facing the lead substrate 3) of the base substrate 2, and is electrically connected to the second mounting electrode (not shown) of the piezoelectric vibrating piece 4.

The second lead-out electrode 37 is provided so as to extend from the second through electrode 33 arranged around a position between the distal end portions 10b and 11b of a pair of vibrating arm portions 10 and 11 toward a support portion 37a arranged on the distal end portion 12b side of the base portion 12 in the axial direction of the center axis O.

The second lead-out electrode 37 supports the distal end portion 12b of the base portion 12 by bump-bonding using the bump B of the support portion 37a in a state of being floated from the surface (the surface facing the lead substrate 3) of the base substrate 2, and is electrically connected to the first mounting electrode (not shown) of the piezoelectric vibrating piece 4.

Accordingly, the second mounting electrode (not shown) of the piezoelectric vibrating piece 4 is provided electrical conduction to the first through electrode 32 through the first lead-out electrode 36. The first mounting electrode (not shown) is provided electrical conduction to the second through electrode 33 through the second lead-out electrode 37.

The base substrate 2 is configured such that the external electrodes 38 and 39 which are electrically connected to a pair of through electrodes 32 and 33 are provided on the first surface.

The first external electrode 38 is electrically connected to the second excitation electrode 16 of the piezoelectric vibrating piece 4 through the first through electrode 32 and the first lead-out electrode 36.

The second external electrode 39 is electrically connected to the first excitation electrode 15 of the piezoelectric vibrating piece 4 through the second through electrode 33 and the second lead-out electrode 37.

The piezoelectric vibrator 1 is activated when a predetermined driving voltage is applied to the external electrodes 38 and 39 formed on the base substrate 2, and a current flows in the excitation electrodes having the first excitation electrode 15 and the second excitation electrode 16 of the piezoelectric vibrating piece 4, thereby causing a pair of vibrating arm portions 10 and 11 to vibrate at a predetermined frequency in a direction close to each other or away from each other.

The vibration of a pair of vibrating arm portions 10 and 11 is used as a time source, a timing source of a control signal, a reference signal source, or the like.

As described above, according to the piezoelectric vibrating piece 4 of this embodiment, the “narrow width portions 13A and 14A” are formed at the base of the base portion 12. Accordingly, since etching residue which occurs in this portion is formed so as to fill the “narrow width portions 13A and 14A”, it is possible to reduce the influence of etching residue as an odd-shaped portion on the mechanical characteristic and the vibration characteristic of the piezoelectric vibrating piece 4. That is, it is possible to identify the shape of the piezoelectric vibrating piece 4 including etching residue with the shape of a piezoelectric vibrating piece in which the “narrow width portions 13A and 14A” are not formed. The “narrow width portions 13A and 14A” are formed, whereby it is possible to reduce the propagation of the vibration in the vibrating arm portions 10 and 11 toward the package side through the base portion 12, that is, to overcome the problem regarding “vibration leakage”.

If the base side surface of the base portion 12 has a curved shape, which is recessed inwardly, to form the “narrow width portions 13A and 14A”, it is possible to reduce the amount of etching residue compared to a case where the narrow width portions are formed in a planar shape.

The side surface of each of the connecting portions 13 and 14 has a curved shape, and the base side surfaces of each of the connecting portions 13 and 14 and the base portion 12 are smoothly connected together, whereby it is possible to more effectively reduce the amount of etching residue.

Since it is not necessary to expand the interval between the base portion 12 and the vibrating arm portions 10 and 11, it is possible to attain reduction in size of the piezoelectric vibrating piece 4.

In the above-described embodiment, although the connecting portions 13 and 14 include curved outer side surfaces 13B and 14B, the invention is not limited thereto, and may include, for example, bent outer side surfaces 13B and 14B having a plurality of planes.

### (Oscillator)

Next, an embodiment of an oscillator according to the invention will be described.

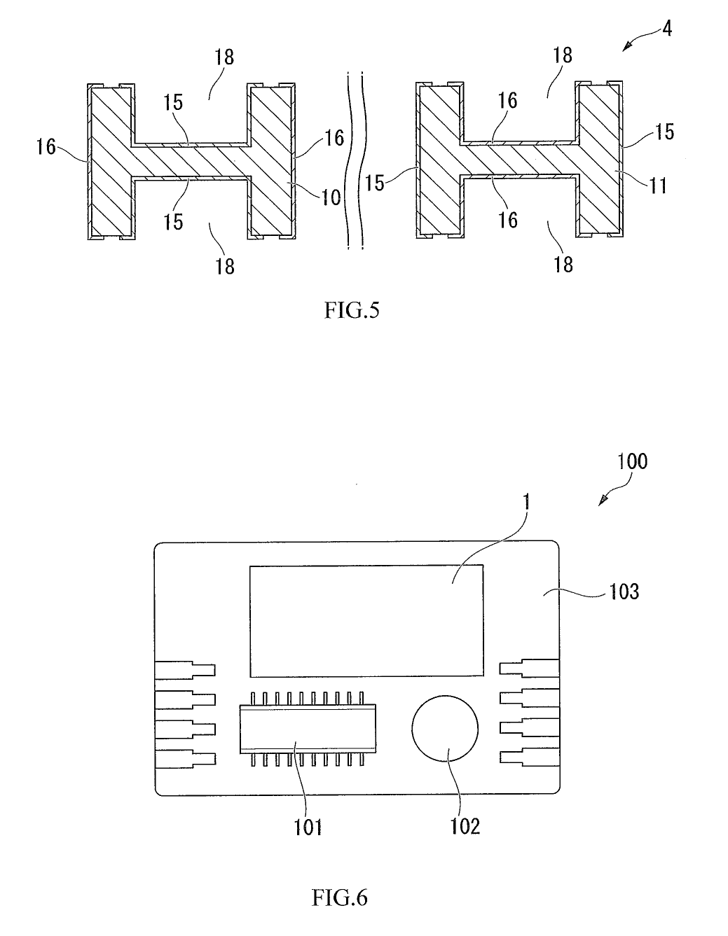

As shown in FIG. 6, an oscillator 100 of this embodiment is configured with the piezoelectric vibrator 1 as an oscillating piece electrically connected to an integrated circuit 101.

The oscillator 100 includes, on a substrate 103, the above-described integrated circuit 101 for an oscillator, an electronic component 102, such as a capacitor, and the piezoelectric vibrating piece 4 of the piezoelectric vibrator 1 arranged near the integrated circuit 101.

The electronic component 102, the integrated circuit 101, and the piezoelectric vibrator 1 are electrically connected together by a wiring pattern (not shown).

Each of the constituent components is molded by resin (not shown).

In the oscillator 100 configured as above, if a voltage is applied to the piezoelectric vibrator 1, the piezoelectric vibrating piece 4 inside the piezoelectric vibrator 1 vibrates.

This vibration is converted to an electrical signal by the piezoelectric characteristic of the piezoelectric vibrating piece 4, and is input to the integrated circuit 101 as the electrical signal. The input electrical signal is subjected to various processes by the integrated circuit 101 and then output as a frequency signal. Accordingly, the piezoelectric vibrator 1 functions as an oscillating piece.

The configuration of the integrated circuit 101 with a real time clock (RTC) module or the like is selectively set as required, whereby it is possible to apply a function of controlling an operation date or time of the apparatus and an external apparatus in addition to a single-function oscillator for a timepiece and the like, or providing time, a calendar, or the like.

As described above, according to the oscillator 100 of this embodiment, since the above-described piezoelectric vibrator 1 is provided, it is possible to provide the oscillator 100 which can obtain high quality with excellent characteristics and reliability.

In addition, it is possible to obtain a stable frequency signal with high precision for a long period.

### (Electronic Apparatus)

Next, an embodiment of an electronic apparatus according to the invention will be described.

As the electronic apparatus, a mobile information apparatus 110 having the above-described piezoelectric vibrator 1 will be described as an example.

The mobile information apparatus 110 of this embodiment is represented by, for example, a mobile phone, and is obtained by developing and improving a watch of the related art. The appearance is similar to a watch, and it is possible to arrange a liquid crystal display in a portion corresponding to a dial plate and to display current time or the like on the screen.

When being used as a communication instrument, it is possible to perform the same communication as a mobile phone of the related art with a speaker and a microphone embedded in an inner side portion of a band by taking the mobile information apparatus from the wrist. However, the mobile information apparatus is significantly reduced in size and weight compared to the mobile phone of the related art.

### (Mobile Information Apparatus)

Next, the configuration of the mobile information apparatus 110 of this embodiment will be described.

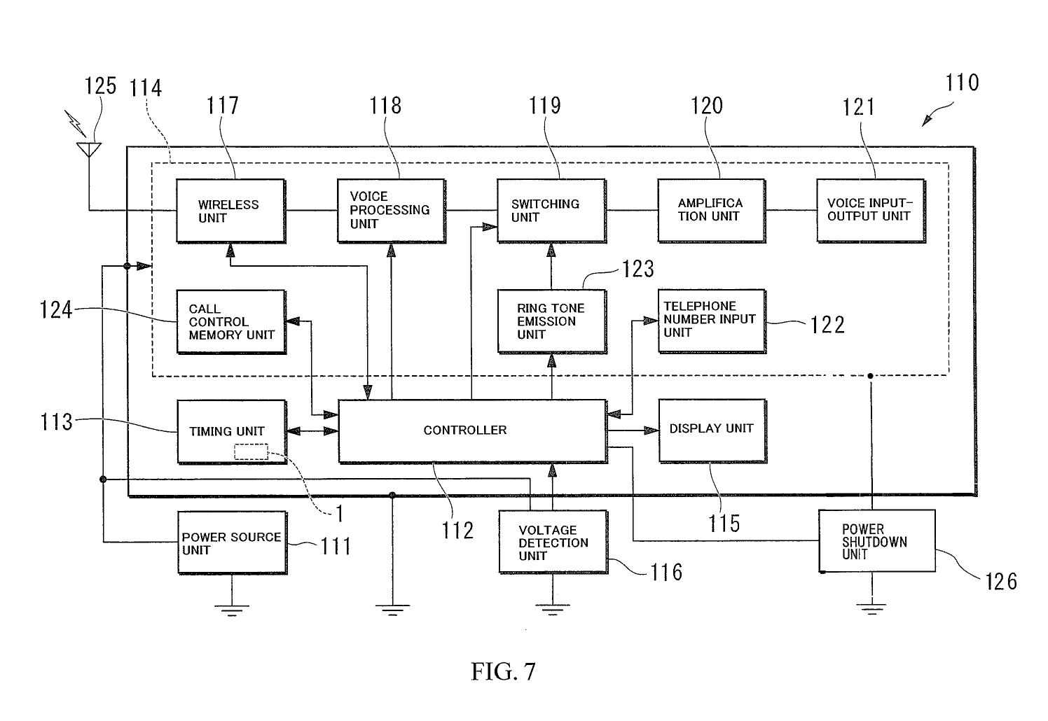

As shown in FIG. 7, the mobile information apparatus 110 includes the piezoelectric vibrator 1, and a power supply unit 111 which supplies power.

The power supply unit 111 is constituted by, for example, a lithium secondary battery.

A control unit 112 which performs various kinds of control, a counter unit 113 which counts time or the like, a communication unit 114 which performs communication with the outside, a display unit 115 which displays various kinds of information, and a voltage detection unit 116 which detects a voltage of each functional unit are connected in parallel to the power supply unit 111.

Power is supplied from the power supply unit 111 to each functional unit.

The control unit 112 controls each functional unit to perform operation control of the entire system, such as transmission and reception of voice data, measurement or display of the current time, and the like.

The control unit 112 includes a ROM in which a program is written in advance, a CPU which reads and executes the program written in the ROM, a RAM which is used as a work area of the CPU, and the like.

The counter unit 113 includes an integrated circuit in which an oscillation circuit, a register circuit, a counter circuit, an interface circuit, and the like are embedded, and the piezoelectric vibrator 1.

If a voltage is applied to the piezoelectric vibrator 1, the piezoelectric vibrating piece 4 vibrates, and this vibration is converted to an electrical signal by the piezoelectric characteristic inherent in crystal and input to the oscillation circuit as the electrical signal. The output of the oscillation circuit is binarized and counted by the register circuit and the counter circuit.

The transmission and reception of the signal to and from the control unit 112 is performed through the interface circuit, and the current time or current date, calendar information, and the like are displayed on the display unit 115.

The communication unit 114 has the same function as the mobile phone of the related art, and includes a wireless unit 117, a voice processing unit 118, a switching unit 119, an amplification unit 120, a voice input/output unit 121, a telephone number input unit 122, a ringtone generation unit 123, and a call control memory unit 124.

The wireless unit 117 performs the transmission and reception of various kinds of data, such as voice data, to and from a base station through an antenna 125.

The voice processing unit 118 encodes and decodes a voice signal input from the wireless unit 117 or the amplification unit 120.

The amplification unit 120 amplifies a signal input from the voice processing unit 118 or the voice input/output unit 121 to a predetermined level.

The voice input/output unit 121 has a speaker, a microphone, and the like, and amplifies a ringtone or voice from a receiver or collects voice.

The ringtone generation unit 123 generates a ringtone according to a call from the base station. The switching unit 119 switches the amplification unit 120, which is connected to the voice processing unit 118, to the ringtone generation unit 123 only when receiving a call, and the ringtone generated in the ringtone generation unit 123 is output to the voice input/output unit 121 through the amplification unit 120.

The call control memory unit 124 stores a program regarding outgoing/incoming call control of communication. The telephone number input unit 122 includes, for example, numeric keypads from 0 to 9 and other keypads, and the numeric keypads and the like are pressed to input the phone number of the called party, or the like.

When the voltage which is applied to each functional unit, such as the control unit 112, by the power supply unit 111 falls below a predetermined value, the voltage detection unit 116 detects the voltage drop and gives notification to the control unit 112. The predetermined voltage value at this time is a value which is set in advance as a minimum voltage necessary for stably operating the communication unit 114, and becomes, for example, about 3 V.

The control unit 112 which is given notification of the voltage drop from the voltage detection unit 116 inhibits the operations of the wireless unit 117, the voice processing unit 118, the switching unit 119, and the ringtone generation unit 123. In particular, it is necessary to inhibit the operation of the wireless unit 117 which has high power consumption. The display unit 115 displays the effect that the communication unit 114 cannot function due to a low remaining battery level.

That is, the voltage detection unit 116 and the control unit 112 can inhibit the operation of the communication unit 114 and can display the effect on the display unit 115. The display may be a text message or may be an x mark on a phone icon displayed on an upper portion of the display surface of the display unit 115 as further intuitive display.

The power supply shutoff unit 126 which can selectively shut off the power supply of a portion regarding the function of the communication unit 114 is provided, thereby reliably stopping the function of the communication unit 114.

As described above, according to the mobile information apparatus 110 of this embodiment, since the above-described piezoelectric vibrator 1 is provided, it is possible to provide the mobile information apparatus 110 which can obtain high quality with excellent characteristics and reliability. In addition, the mobile information apparatus 110 can display stable timepiece information with high precision for a long period.

### (Radio-Controlled Timepiece)

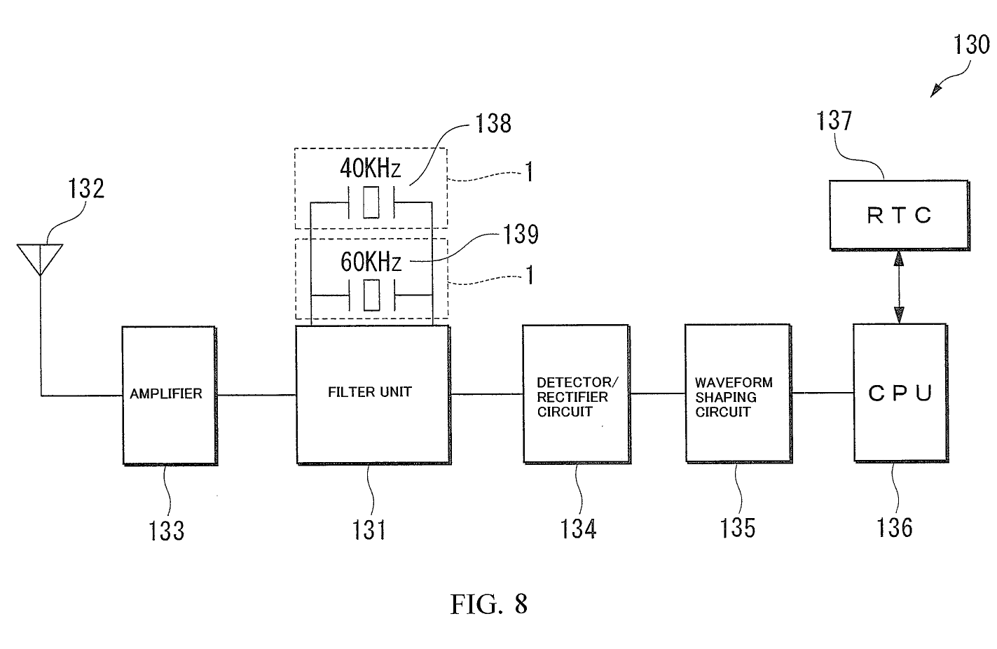

Next, an embodiment of a radio-controlled timepiece according to the invention will be described referring to FIG. 8.

As shown in FIG. 8, a radio-controlled timepiece 130 of this embodiment includes the piezoelectric vibrator 1 which is electrically connected to a filter unit 131, and is a timepiece which includes a function of receiving standard radio waves including timepiece information and automatically correcting and displaying correct time.

Transmitting stations (transmitter stations) which transmit the standard radio waves are in Fukushima-ken (40 kHz) and Saga-ken (60 kHz) in Japan, and respectively transmit the standard radio waves. Since long waves, such as 40 kHz or 60 kHz, have both a property of ground-wave propagation and a property of propagation by reflection between the ionosphere and the ground, a propagation range is large and the above-described two transmitting stations provide full coverage of Japan.

Hereinafter, the functional configuration of the radio-controlled timepiece 130 will be described in detail.

An antenna 132 receives a standard long wave of 40 kHz or 60 kHz. The standard long wave is obtained by applying time information, called a time code, to a carrier wave of 40 kHz or 60 kHz through AM modulation. The received standard long wave is amplified by an amplifier 133 and is filtered and synchronized by the filter unit 131 having a plurality of piezoelectric vibrators 1.

In this embodiment, the piezoelectric vibrator 1 includes crystal vibrator units 138 and 139 which have resonance frequencies of 40 kHz and 60 kHz the same as the above-described carrier frequency.

The filtered signal of the predetermined frequency is detected and demodulated by a detection and rectification circuit 134. Then, the time code is extracted through the waveform shaping circuit 135 and counted in a CPU 136.

The CPU 136 reads information regarding the current year, date, day, time, and the like. The read information is reflected in the RTC 137, and correct time information is displayed.

Since the carrier wave is 40 kHz or 60 kHz, the vibrator having a tuning fork type structure described above is suitable for the crystal vibrator units 138 and 139.

Although the above description is described with Japan as an example, the frequency of the standard long wave differs by country. For example, the standard radio wave of 77.5 KHz is used in Germany. Accordingly, when the radio-controlled timepiece 130 which can be used overseas is embedded in a mobile apparatus, another piezoelectric vibrator 1 with a frequency different from that in Japan is required.

As described above, according to the radio-controlled timepiece 130 of this embodiment, since the above-described piezoelectric vibrator 1 is provided, it is possible to provide the radio-controlled timepiece 130 which can obtain high quality with excellent characteristics and reliability. In addition, the radio- controlled timepiece 130 can stably count time with high precision for a long period.

The technical scope of the invention is not limited to the above-described embodiment, and various changes may be made within a range without departing from the spirit of the invention.

For example, in the above-described embodiment, although the piezoelectric vibrating piece 4 of the invention is used in the surface mounting type piezoelectric vibrator 1, the invention is not limited thereto, and for example, a ceramic package type piezoelectric vibrator or a surface mounting type vibrator which is obtained by fixing a cylinder package type piezoelectric vibrator using a mold resin portion may be used.

What is claimed is:

1. A piezoelectric vibrating piece comprising:
a pair of vibrating arm portions;
a base portion which is arranged between the pair of vibrating arm portions, and
connecting portions which connect proximal end portions of the vibrating arm portions and a proximal end portion of the base portion,
wherein narrow width portions are provided at the base of the base portion.

2. A piezoelectric vibrating piece of claim 1, wherein the narrow width portions are formed such that the side surface of the base portion has a curved shape which is recessed inwardly.

3. A piezoelectric vibrating piece of claim 1, wherein the side surface of each of the connecting portions has a curved shape and is connected to the curved shape of the side surface of the base portion.

4. A piezoelectric vibrator comprising the piezoelectric vibrating piece of claim 1 sealed airtight in a package.

5. An oscillator comprising the piezoelectric vibrator of claim 4 electrically connected to an integrated circuit.

6. An electronic apparatus comprising the piezoelectric vibrator of claim 4 electrically connected to a counter unit.

7. A radio-controlled timepiece comprising the piezoelectric vibrator of claim 4 electrically connected to a filter unit.
